(19) United States
(12) Patent Application Publication
(10) Pub. No.: US 2026/0123133 A1
(43) Pub. Date: Apr. 30, 2026

(54) MICROLED VERTICAL REDUNDANCY TO COVER FOR DEFECTIVE PIXELS IN DISPLAYS AND METHODS RELATED THERETO

(71) Applicant: Adeia Semiconductor Bonding Technologies Inc., San Jose, CA (US)

(72) Inventors: Oliver Zhao, Daly City, CA (US); Rajesh Katkar, Milpitas, CA (US)

(21) Appl. No.: 18/952,803

(22) Filed: Nov. 19, 2024

Related U.S. Application Data
(60) Provisional application No. 63/714,736, filed on Oct. 31, 2024.

(51) Int. Cl. H10H 29/39; H10H 29/01; H10H 29/856

(52) U.S. Cl. CPC H10H 29/39; H10H 29/012; H10H 29/0364; H10H 29/856

(57) ABSTRACT

A display device comprises a plurality of first LEDs disposed in a first passivation layer. Each first LED has a first electrode disposed on the respective first LED and a second electrode that is electrically coupled to a control device. A contact of at least one second LED is directly bonded to the first electrode of at least one first LED. The second LED and the first electrode of the at least one first LED are disposed in a second passivation layer. An electrode of the second LED is electrically connected to a same control device that the second electrode of the at least one first LED is connected to.

### CROSS REFERENCE TO RELATED APPLICATION

This application claims the benefit of U.S. Provisional Patent Application No. 63/714,736 , filed Oct. 31, 2024, which is hereby incorporated by reference herein in its entirety.

### FIELD

The present disclosure relates to display devices and structures and methods of manufacturing the same.

### BACKGROUND

Micro light emitting diode (microLED, micro-LED, μLED, or μ-LED) displays may provide benefits of higher resolution and increased brightness when compared to conventional display technologies. A typical microLED display may be a heterogeneous system that integrates microLEDs and control devices manufactured using different substrates and different process flows. Unfortunately, current manufacturing processes used to address defective pixels on a display may be prohibitively expensive and/or consume valuable area on a display. Accordingly, there exists a need in the art for improved microLED displays and methods of manufacturing the same.

### SUMMARY

Embodiments herein provide for display devices using vertical LED redundancy to cover for defective pixels in displays and methods for manufacturing the same. In some embodiments, the display or display device is an LED display comprising LEDs of any suitable size such as greater than about 500 microns in size, equal to or less than about 500 microns in size, as greater than about 100 microns in size, equal to or less than about 100 microns in size, equal to or less than about 50 microns in size, or equal to or less than about 5 microns in size. In some embodiments, the display is a microLED display (e.g., comprising LEDs equal to or less than about 100 microns, 50 microns, or 5 microns in size). Advantageously, display devices using vertical LED redundancy (e.g., vertically stacking a working LED on top of a defective LED) may be used to cover for defective pixels in displays. By vertically stacking a working LED with opposite direction of emission to the defective LED, and by bonding the working LED to the existing electrodes of the defective LED (or pixel), the working LED can cover for the defective LED without using additional space on the display device or additional driving circuitry. Additionally, embodiments herein may cover for defective LEDs in a display device without use of additional pads by utilizing existing layers of the display device for bonding.

A first general aspect includes a display device. The display device includes a plurality of first LEDs disposed in a first passivation layer. Each first LED has a first electrode disposed on the respective first LED and a second electrode that is electrically coupled to a control device. A contact of at least one second LED is directly bonded to a first electrode of at least one first LED, and the at least one second LED and the first electrode of the at least one first LED are disposed in a second passivation layer. An electrode of the at least one second LED is electrically connected to the same control device that the second electrode of the at least one first LED is connected to.

In some embodiments, the plurality of first LEDs are bottom-emitting LEDs, and the at least one second LED is a top-emitting LED. Each of the plurality of first LEDs may be disposed in a reflective layer disposed in the first passivation layer. The reflective layer may be surrounding bottom and side surfaces of a respective first LEDs to direct light emitted from the respective first LEDs towards a display surface. The at least one second LED may comprise a reflective layer on sidewalls of the at least one second LED to direct light emitted from the at least one second LED towards a display surface. In other embodiments, the plurality of first LEDs are top-emitting LEDs, and the at least one second LED is a bottom-emitting LED.

In some embodiments, the at least one first LED and the at least one second LED have different geometric structures. Each of the first LEDs may be embedded in or on top of a sidewall mirror.

In some embodiments, the electrode of the at least one second LED is wire bonded to a bond pad to connect to the same control device that the second electrode of the at least one first LED is connected to. The first electrode of each first LED may comprise indium tin oxide or copper. The display device may be a microLED display device.

A second general aspect includes a method for manufacturing a display device. The method comprises providing a substrate comprising a plurality of first LEDs disposed in a first passivation layer. Each first LED comprises a respective first electrode and a respective second electrode. The method further comprises directly bonding a contact of at least one second LED to at least one first electrode of at least one first LED.

In some embodiments, the method further comprises depositing a second passivation layer to dispose the second LED in the second passivation layer. Subsequent to depositing the second passivation layer the method may further comprise forming electrical vias in the second passivation layer and the first passivation layer by first creating an opening in the second passivation layer and the first passivation layer to expose the second electrode of the at least one first LED. The opening may be made adjacent to the at least one first LED and the at least one second LED, and a conductive material may be deposited in the opening to connect the second electrode of the at least one first LED to the at least one second LED.

In some embodiments, the first and second passivation layer comprises polyimide and creating the opening comprises laser ablating a portion of the first and second passivation layers. In some embodiments, prior to directly bonding, the method may include testing luminance values of each first LED to identify the at least one first LED as a defective LED.

In some embodiments, providing the substrate comprises attaching the plurality of first LEDs to a complementary metal-oxide semiconductor (CMOS) and/or thin film transistor (TFT) backplane. Providing the substrate may include attaching the plurality of first LEDs to a reconstituted wafer comprising control devices. The method may further include wire bonding the electrode of the at least one second LED to a bond pad to connect the electrode of the at least one second LED to the second electrode of the at least one first LED.

A third general aspect includes a display device. The display device comprises a first substrate and a second substrate. The first substrate comprises a plurality of control devices. The second substrate comprises a plurality of first LEDs embedded in a dielectric layer. A contact of at least one second LED is directly bonded to the second substrate to connect the at least one second LED to a control device in the first substrate through at least one via in the second substrate.

In some embodiments, the second substrate is a top second substrate. The dielectric layer may be a first dielectric layer. The display device may further comprise a bottom second substrate. The bottom second substrate may comprise a plurality of third LEDs embedded in a second dielectric layer. The control device may be connected to the at least one second LED through at least one via in the bottom second substrate. The display device may further comprise an intermediate second substrate. The intermediate second substrate may comprise a plurality of fourth LEDs embedded in a third dielectric layer. The control device may be connected to the at least one second LED through at least one via in the intermediate second substrate.

A fourth general aspect includes a method for manufacturing a display device. The method includes providing a first substrate and a second substrate. The first substrate comprises a plurality of control devices. The second substrate comprises a plurality of first LEDs embedded in a dielectric layer. The method includes directly bonding a contact of at least one second LED to the second substate to connect the at least one second LED to a control device in the first substrate through at least one via in the second substrate.

In some embodiments, the second substrate is a top second substrate. The dielectric layer may be a first dielectric layer. The method may further comprise directly bonding a bottom second substrate to the first substrate. The bottom second substrate may comprise a plurality of third LEDs embedded in a second dielectric layer. The control device may be connected to the at least one second LED through at least one via in the bottom second substrate. The method may further comprise directly bonding an intermediate second substrate to the bottom second substrate. The intermediate second substrate may comprise a plurality of fourth LEDs embedded in a third dielectric layer. The control device may be connected to the at least one second LED through at least one via in the intermediate second substrate.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1B schematically illustrate example views of a display device, according to some embodiments;

FIGS. 2-4 schematically illustrate example cross section views of a display device, according to some embodiments;

FIGS. 5A-5B schematically illustrate example views of a display device, according to some embodiments;

FIGS. 6A-6C schematically illustrate aspects of example methods of forming a display device, according to some embodiments;

FIG. 7 schematically illustrates forming a portion of display, according to some embodiments; and

FIGS. 8A-8B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for improved (e.g., more efficient) manufacturing of displays (e.g., display devices, LED displays, LED display devices, micro-LED displays, micro-LED display devices) by vertical LED redundancy (e.g., vertically stacking a working LED on top of a defective LED) to cover for defective pixels in displays. By vertically stacking a working LED with opposite direction of emission to the defective LED, and by bonding the working LED to the existing electrodes of the defective LED (or pixel), the working LED can cover for the defective LED without using additional space on the display device or additional driving circuitry. Additionally, by utilizing existing layers of the display device for bonding, LEDs may be efficiently placed over a defective LED without the need of additional complex tooling. Advantageously, the stacking of an LED over a defective LED may allow simple electrical coupling (e.g., recycling the circuitry of the defective LED for the stacked LED) and may reduce the time it takes to manufacture a display device (e.g., by not requiring complex circuitry). Additionally, the vertical stacking and bonding of an LED over a defective LED may allow for higher luminance values per pixel to occur, increasing product quality output.

The integration of microLED technology in displays may offer significant benefits in terms of resolution, energy efficiency, brightness, and overall display performance. The ability to precisely control each microLED may allow for better luminous flux with a higher dynamic range and a broader spectrum of colors, leading to more vibrant and lifelike images, which may be beneficial for applications requiring high-definition visuals, such as advanced televisions, smartphones, wearable devices, automotives, and virtual/augmented reality devices. Additionally, the energy efficiency of microLEDs may translate into longer battery life for portable devices and lower power consumption for larger displays. The versatility of microLED technology extends to the potential for flexible and transparent displays, opening new avenues for innovative design and application in various fields, ranging from consumer electronics to specialized industrial and medical equipment. MicroLED displays may have higher brightness, increased power efficiency, longer lifetime, more durability, and may be more suitable for stretchable and transparent display applications over light-crystal displays (LCD) or organic light emitting diode (OLED) displays.

However, microLED displays may be costly to fabricate and often involve time-consuming manufacturing techniques, such as the redundant subpixel process, to address defective pixels and non-functional microLED chips on a display. For example, the redundant subpixel process, while effective for addressing pixel defects, can introduce significant inefficiencies in microLED display manufacturing. For instance, in a microLED ultra-high density (UHD) 4K RGB (red, green, blue) display comprising approximately 25 million microLEDs (e.g., about 8.3 million pixels, each pixel containing a red, green, and blue microLED), additional redundant microLEDs are added for every pixel. This not only increases the total number of microLEDs but also extends assembly time and uses additional lateral area of the display device for these subpixels. With a die bonding machine capable of transferring only 5 to 10 microLEDs per second, the inclusion of redundant subpixels can extend manufacturing time by hundreds of hours for each display. As a result, the redundant subpixel process, while beneficial for yield, imposes a high cost and time burden on production. Accordingly, there exists a need in the art for improved microLED displays with a streamlined processes to fix defective pixels and the methods of manufacturing the same.

In some approaches, by utilizing existing circuitry (e.g., electrode) of a defective LED, a new LED may be bonded to the existing circuitry (e.g., electrode) and cover the defective LED. For an RGB display, any suitable color may be vertically stacked and subsequently bonded to a respective defective color (e.g., red to red, blue to blue, and green to green). The process may include pick-and-place machines to place an LED over a respective defective LED.

Advantageously, the displays (e.g., microLED displays) and manufacturing methods described herein may provide for reduced pixel sizes, manufacturing costs, and manufacturing time compared to conventional redundant subpixel process. By enabling the means to fix each defective LED on a display device, vertically, the need of additional subpixels may be no longer required, thereby increasing the available space emitted from each pixel.

A size of a pixel for a display may vary depending on the application—about 5 microns or less than about 5 microns, less than about 10 microns, or about 5-10 microns for augmented reality/virtual reality (AR/VR) or mixed reality (MR) applications, about 30-50 microns for watches, about 40-60 microns or about 50-70 microns for cellphones, about 300-400 microns or about 350 microns for computer monitors and screens, about 500-1000 microns or greater than about 0.5 mm for televisions. The size of the source LED occupying the pixel may not match the size of the pixel itself. Light emitted from a small LED can fill all of the pixel area of a large pixel and help create a continuous image. The ratio of pixel size to LED size can range from about 1.5 to 3 in AR/VR or MR applications (e.g., pixel size is about 1.5x LED size to about 3x LED size) to over 100 (e.g., pixel size greater than about 100x LED size) in a television application. The smaller the ratio (e.g., area of pixel to area of LED), the larger the LED fill factor, and more light would be output. A larger LED fill factor indicates higher brightness requirement of the application. Different applications have varying luminous flux density requirement (e.g., brightness requirement). While AR/VR applications require extremely bright light so the projected images may be visible in extreme conditions (e.g., bright daylight), brightness requirements may be less stringent for other applications such as monitors and TVs in which the screens which have a larger viewing distance (e.g., are comparatively far away from an eye of a viewer). In some embodiments, a pixel comprises a plurality of source LEDs (e.g., an RGB pixel comprises 3 LEDs per pixel, an RGBG (red, green, blue, green) pixel comprises four LEDs per pixel), and a control circuit may be shared by several pixels.

The shorter the distance between the screen and viewer (e.g., an eye of a viewer) in an application, the smaller the pixel size requirement to provide a continuous image without a visible gap between the neighboring pixels. In AR/VR or MR applications, where a display may be about 1-2 cm from an eye of a viewer, pixel sizes may be typically less than 5 microns, and there may be a challenge to achieve high pixel density and to ensure uniformity and brightness of pixels for an immersive visual experience. Such applications may require smaller pixels (e.g. <5-10um) and larger fill factor. The embodiments herein describe approaches which may enhance the density and uniformity of the pixels and/or improve the light emission efficiency. In television applications where pixel sizes can be greater than 0.5 mm (e.g., the screen is typically several feet away from the eye of a viewer; hence larger pixel and smaller LED fill factor would work), a stacked LED structure may be used for larger pixel requirements. In some embodiments, a pixel may include additional LEDs (e.g., other than RGB, such as white, cyan, etc.) to achieve an enhanced color gamut beyond the standard RGB and/or to add more light emission to improve brightness.

In some embodiments, dielectrics specifically tuned to certain color spectrums may be used within the optical path of the display for improved efficiency. Suitable materials for these dielectrics may include polystyrene, cyclic olefin polymer/cyclic olefin copolymers, polycarbonate, PMMA (Acrylic), or Ultraviolet Acrylic. These materials are known for their high transmission in the visible spectrum, which is relevant for improved efficiency and functionality of an RGB display.

As described below, semiconductor substrates, display substrates, LED display substrates, or micro-LED display substrates herein generally have a “device side,” e.g., the side on which semiconductor device elements are fabricated, such as transistors, resistors, capacitors, micro-LEDs, driver circuits, and interconnects, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250°° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

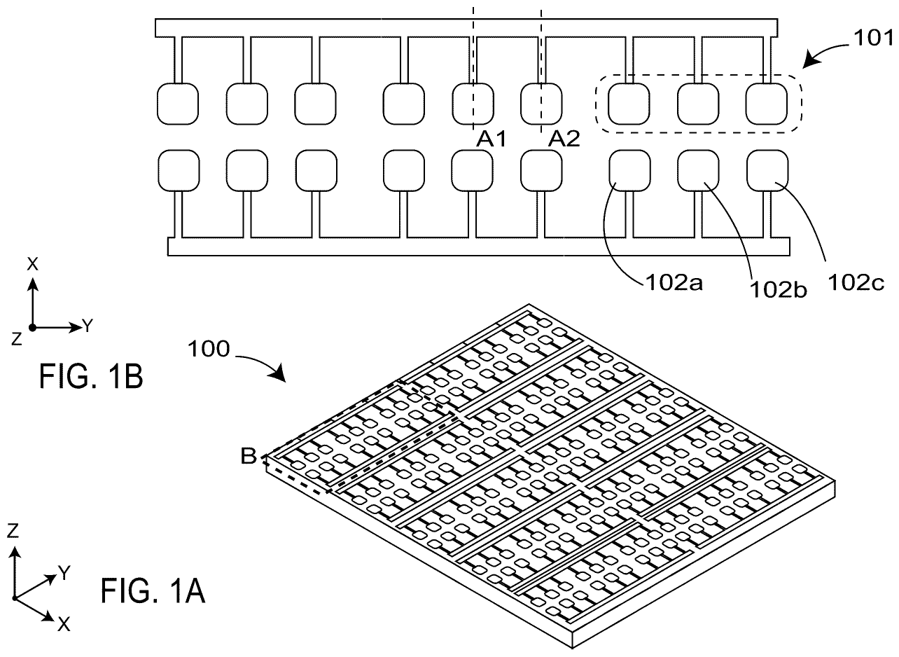

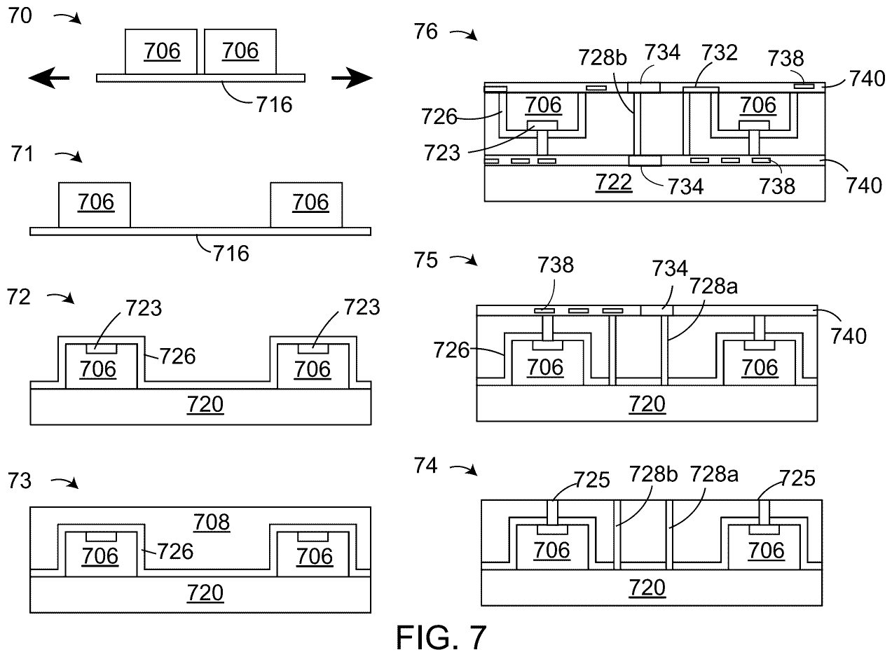

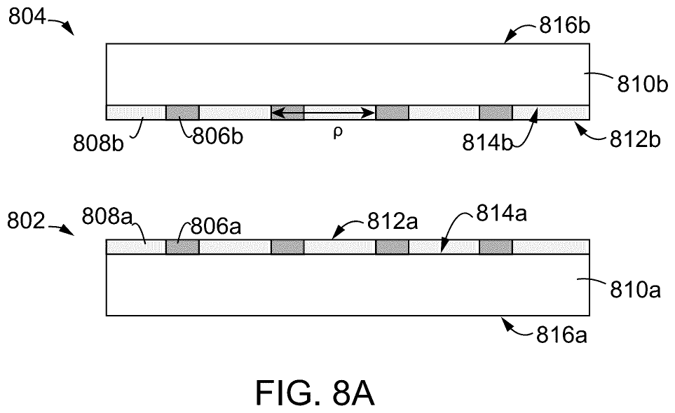

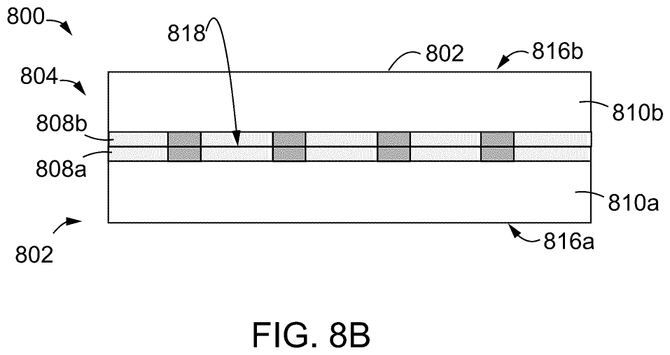

FIGS. 1A-1B, 2-4, 5A-5B and 6A-6C schematically illustrate various embodiments of a display. In some embodiments, the display may be a microLED display. For example, the LEDs 102, 202, 302, 322, 422, 506, 512, 518, and 706 may be microLEDs, with sizes equal to or less than about 100 microns, 50 microns, or 5 microns. FIG. 7 details the method used for spacing LEDs in preparation for a stackable, heterogeneous reconstitution. FIGS. 8A-8B illustrate a hybrid bonding method for bonding substrates (e.g., substrates comprising LEDs to substrates comprising LEDs, substrates comprising LEDs to substrates comprising control devices and/or LEDs).

In some embodiments, the display (e.g., display 100, display 200, display 300, display 400, display 500, or any suitable display described throughout the present disclosure) may be an LED display and comprise LEDs greater than about 500 microns in size, or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

A display may comprise any suitable number of pixels (e.g., one or more pixels, a plurality of pixels). Although a display (e.g., display 100, display 200, display 300, display 400, display 500, or any suitable display described throughout the present disclosure) may show a specific number of pixels (e.g., one, three, twenty five, etc.), in some embodiments the display (e.g., display 100, display 200, display 300, display 400, display 500, or any suitable display described throughout the present disclosure) may comprise any suitable number of pixels (e.g., hundreds, thousands, millions, etc.).

A pixel may comprise any suitable number, shape, and color of sub-pixels or LEDs (e.g., one, two, three or more LEDs). Although a pixel (e.g., pixel 101, pixel 501, or any suitable pixel described in the present disclosure) may show a specific number of sub-pixels (e.g., three), in some embodiments a pixel (e.g., pixel 101, pixel 501, or any suitable pixel described in the present disclosure) may have any suitable number of sub-pixels or LEDs (e.g., one, two, four, five or more, etc.). Although the sub-pixels or LEDs (e.g., LEDs 102, 202, 302, 322, 422, 506, 512, 518, and 706 or any suitable LED described in the present disclosure) are shown as similarly shaped rectangles, in some embodiments the sub-pixels or LEDs (e.g., LEDs 102, 202, 302, 322, 422, 506, 512r, 512g, 512b, 518, and 706 or any suitable LED described in the present disclosure) may be of any suitable shape. In certain embodiments, advancements in colored phosphors may permit the addition of a fourth color, like a green variant or cyan, to enhance the color gamut. In some embodiments, a pixel (e.g., LEDs 102, 202, 302, 322, 422, 506, 512r, 512g, 512b, 518, and 706 or any suitable LED described in the present disclosure) may comprise four sub-pixels comprising a red LED, a blue LED, and two green LEDs. In some embodiments, LEDs (e.g., LEDs 102, 202, 302, 322, 422, 506, 512r, 512g, 512b, 518, and 706 or any suitable LED described in the present disclosure) of a pixel (e.g., pixel 101, pixel 501, or any suitable pixel described in the present disclosure) may also be electronically connected to a control device (e.g., singulated integrated circuit, or readout integrated circuits).

FIGS. 1A-1B schematically illustrate example views of a display 100 (e.g., display device, LED display or display device, micro-LED display or display device). FIG. 1A shows an example isometric top-down view of the display 100. FIG. 1B shows an example top-down view of display 100 from the dotted box B in FIG. 1A.

Pixel 101 comprises three sub-pixels or LEDs (e.g., LED 102a, LED 102b, LED 102c). Each sub-pixel or LED may emit a distinct color of light. For example, LED 102a, LED 102b, LED 102c may comprise red (R), green (G), and blue (B) LEDs respectively. The red LEDs may comprise a phosphor that emits red light (e.g., AlGaInP, AlGaAs, etc.). The green LEDs may comprise a phosphor that emits green light. The blue LEDs may comprise a phosphor that emits blue light. In some embodiments, LEDs (e.g., LED 102c) may be green or blue LEDs with a quantum dot layer or phosphor to down convert the green or blue emitted light to red light.

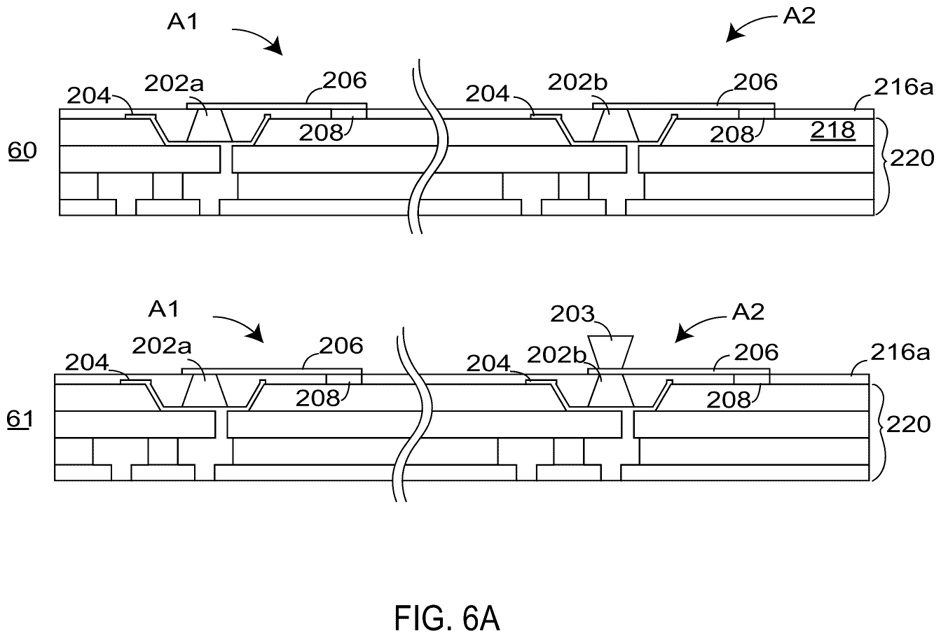

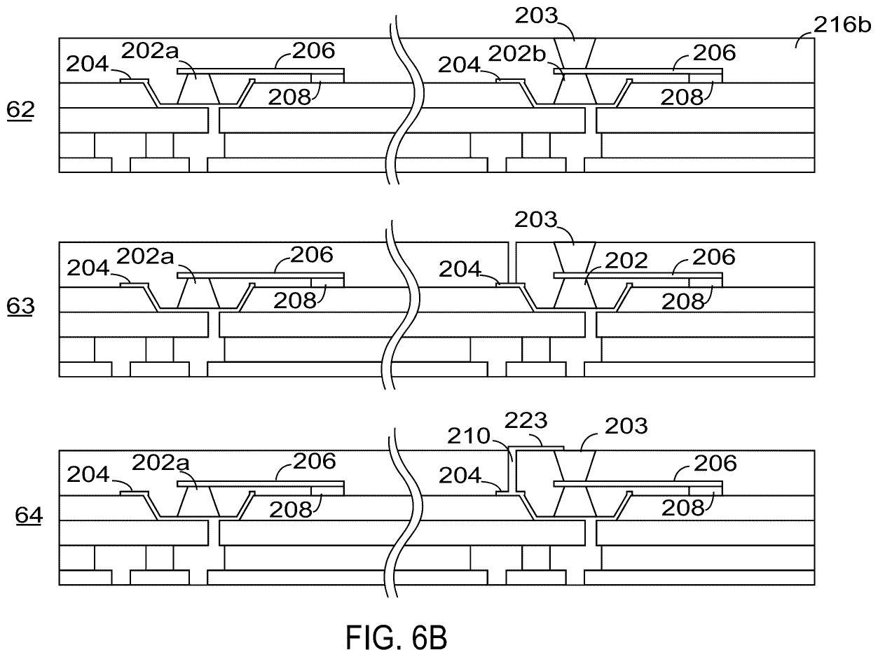

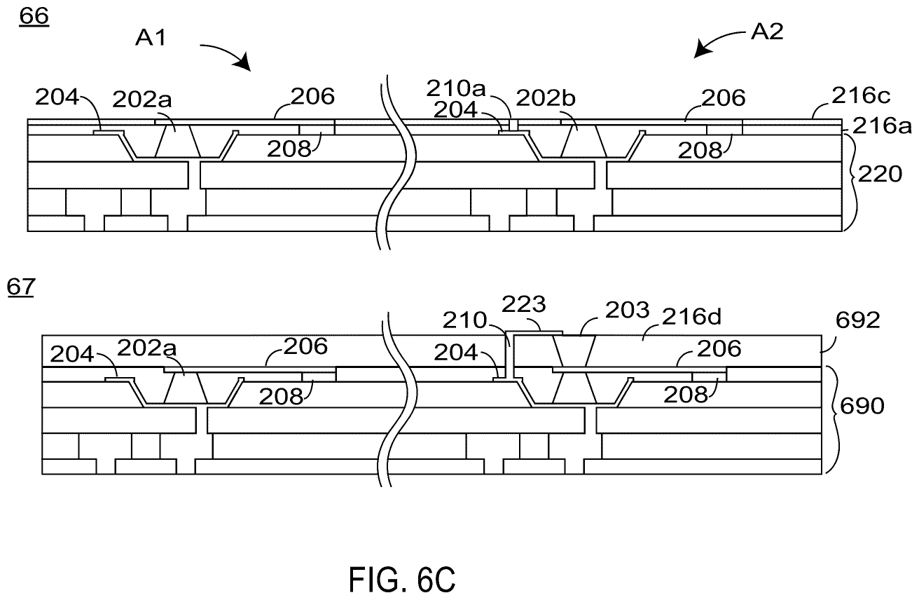

In some embodiments, an LED may be determined to be defective (e.g., an LED at line A2 at FIG. 1B). Details regarding testing LEDs or detecting defective LEDs may be found in the description at block 60 of FIG. 6A. If an LED is determined to be defective, a working LED may be stacked on top of the defective LED.

In some embodiments, the display 100 is a liquid crystal display (LCD) or Liquid Crystal on Silicon (LCOS) display. In some embodiments, the display 100 is a charged-coupled device (CCD) or a CMOS image sensor.

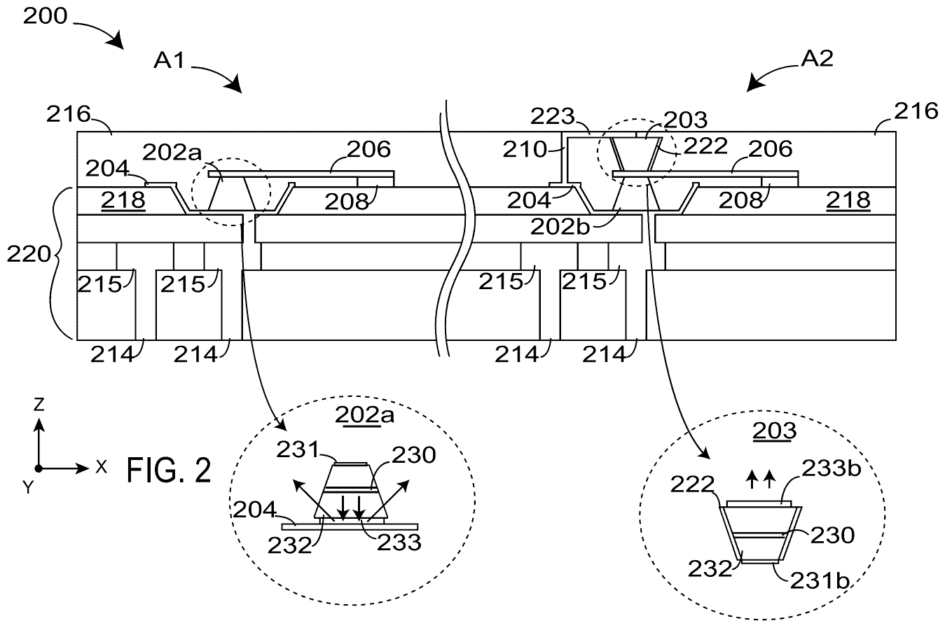

FIG. 2 schematically illustrates an example cross section view a display device 200. In some embodiments, display device 200 corresponds to (e.g., is similar to or the same as) display device 100, and FIG. 2 shows an example cross sectional view taken from the dotted lines A1 and A2 of the display device 100 in FIG. 1B. The display device 200 comprises a substrate 220, a working LED 202a (e.g., at the dotted line A1 from FIG. 1B) and a defective LED 202b (e.g., at the dotted line A2 from FIG. 1B) formed on substrate 220, and a replacement LED 203 attached or directly bonded to the defective LED 202b.

In some embodiments, the substrate 220 may be a transistor matrix, a silicon backplane, or TFT backplane. The substrate 220 may include control devices to drive the LEDs. The substrate 220 may comprise interconnects 215, vias 214, and integrated circuits (ICs). For, example ICs may be driver circuitry, and each pixel and/or LED may have a corresponding circuitry for driving the pixel and/or LED. The interconnects 215 and vias 214 may connect and communicatively couple electrical components (e.g., ICs) of the substrate 220 to electrical components (e.g., LEDs) of the display device 200. The interconnects 215 and vias 214 may comprise a conductive material (e.g., Cu, Al, ITO, or any suitable conductive material).

In some embodiments, the substrate 220 may comprise a material layer 218 in which a reflective layer (e.g., reflective bank, reflective structure, electrode) may be formed. The material layer 218 may comprise an insulating material, a dielectric and/or an oxide. In some embodiments, the material layer 218 may comprise an organic or inorganic material. In some embodiments, the material layer 218 may be opaque, transparent, or semi-transparent to the visible wavelength. For example, the material layer 218 may comprise of acrylic, photoresist, silicon oxide (SiO2), silicon nitride (SiNx), poly(methyl methacrylate) (PMMA), benzocyclobutene (BCB), polyimide, or any suitable material. An opening may be formed in the material layer 218 and a reflective layer may be formed in the opening. The reflective layer may comprise a conductive and reflective material (e.g., Cu, ITO, Au, Al, Ag, or any suitable conductive and reflective material). In some embodiments, the reflective layer is a second electrode 204 of a first LED (e.g., LED 202a, 202b). In some embodiments, the second electrode 204 (e.g., reflective bank, reflective layer) of the first LED (e.g., LED 202a, 202b) is communicatively coupled to the driving circuitry of the display device 200 through interconnects 215, vias 214.

In some embodiments, the display device 200 comprises a plurality of first LEDs (e.g., LEDs 202a, 202b or LEDs 102a, 102b, 102c of FIG. 1B). The first LEDs may be bottom-emitting LEDs. Each first LED 202a, 202b may be electrically connected to and/or in contact with an electrode (e.g., first electrode 206 and a second electrode 204). A first electrode 206 may be disposed on top of each first LED (e.g., LEDs 202a, 202b) and comprise a conductive material (e.g., Cu, ITO, Au, Al, Ag, any suitable conductive material). In some embodiments, the first electrode 206 may comprise any suitable conductive and transparent material (e.g., ITO, transparent conductive oxide). The second electrode 204 may comprise a conductive material (e.g., Cu, ITO, Au, Al, Ag, any suitable conductive material). In some embodiments, the second electrode 204 may comprise any suitable conductive and reflective material.

A close-up illustration is provided for the first LED 202a, outlined by the dotted circle. The embodiments from the close-up illustration may be applied to any applicable LED described in this disclosure (e.g., any of the first LEDs, or second LEDs). In one example, the first LED 202a may have similar features to the display device 100 described above. In some embodiments, as illustrated in the dotted circle, the first LED 202a is a bottom emitting LED (e.g., light emission arrows initially point downwards along the z-axis). The LED may comprise an active layer 230 (e.g., multiple quantum well structures) and semiconductor layer (or layers) 232 on either side of the active layer 230 (e.g., p-doped and n-doped layers, respectively).

In some embodiments, the first LED 202a comprises a bottom contact or second contact 233 (e.g., bonding pad) and a top contact or first contact 231 (e.g., bonding pad). The bottom contact or second contact 233 (e.g., bonding pad) may be used to bond the first LED 202a to the second electrode 204. Similarly, the top contact 231 (e.g., bonding pad) may be used to bond the first LED 202a to the first electrode 206. Each contact (e.g., bottom contact 233 and top contact 231) may comprise a conductive material for direct bonding and may comprise any suitable conductive material (e.g., metal, Cu, transparent conductive oxide, ITO, etc.). In some embodiments, each contact (e.g., bottom contact 233 and top contact 231) may be the same as or similar to the bonding interfaces described below (e.g., the conductive features 806a, 806b of FIG. 8A).

In some embodiments, a passivation layer 216 is disposed over the substrate 220 of the display device 200. In some embodiments, the passivation layer 216 may be transparent or semi-transparent to the visible wavelengths (e.g., wavelengths emitted from the first LEDs 202a 202b of the display device 200). The passivation layer 216 may comprise of dielectrics and/or oxides. Some specific examples include but are not limited to epoxy, acrylic (polyacrylate), poly methacrylate (PMMA), poly-carbonate (PC), benzocyclobutene (BCB), polyimide, and polyester, or any suitable material. In some embodiments, the passivation layer 216 may also cover any portions of the second electrode 204 (e.g., reflector bank, reflective layer) to prevent possible shorting.

In some embodiments, a connector 208, may be disposed in the passivation layer 216. The connector 208 may electrically connect the first electrode 206 to the driving circuitry of the display device 200. The connector 208 may comprise a conductive material (e.g., Cu, ITO, or any suitable conductive and reflective material).

In some embodiments, the display device 200 comprises a plurality of second LEDs (e.g., LEDs 203, 322, 422, 518). The second LED may be top-emitting LED (e.g., second LED 203) vertically adjacent to a bottom-emitting first LED (e.g., 202b). In some embodiments, the top-emitting LED is the same as or similar to the bottom-emitting LED but upside-down (e.g., oriented so that light emits in an opposite direction). Each second LED 203 may be electrically connected to and/or in contact with an electrode (e.g., first electrode 206 and a second electrode 204). The first electrode 206 may comprise a conductive material (e.g., Cu, ITO or any suitable conductive material). The second electrode 204 may comprise a conductive and/or reflective material (e.g., Cu, ITO, Au, Al, Ag, or any suitable conductive and reflective material). The second LED 203 may be electrically connected to the second electrode 204 of the first LED 202b by electrical connects.

A close-up illustration is provided for the second LED 203, outlined by the dotted circle. The embodiments from the close-up illustration may be applied to any applicable LED described in this disclosure (e.g., any of the first LEDs, or second LEDs). In one example, the second LED 203 may have similar features to the display device 100 described above. In some embodiments, as illustrated in the dotted circle, the second LED 203 is a top emitting LED (e.g., light emission arrows initially point upwards along the z-axis). The LED may comprise an active layer 230 (e.g., multiple quantum well structure) and semiconductor layer (or layers) 232 on either side of the active layer 230 (e.g., p-doped and n-doped layers, respectively).

In some embodiments, the second LED 203 comprises a bottom contact or first contact 231b (e.g., bonding pad) and a top contact or second contact 233b (e.g., bonding pad). The bottom contact 231b (e.g., bonding pad) may be used to bond the second LED 203 to the first electrode 206 of the first LED 202b. Similarly, the top contact 233b (e.g., bonding pad) may be used to bond the second LED 203 to a second electrode 223. The second electrode 223 of the second LED 203 may be bonded to the second electrode 204 of a first LED 202b by a via 210. Each contact (e.g., bottom contact 231b and top contact 233b) may comprise a conductive material for direct bonding and may comprise any suitable conductive material (e.g., metal, Cu, transparent conductive oxide, ITO, etc.). In some embodiments, each contact (e.g., bottom contact 231b and top contact 233b) may be the same as or similar to the bonding interfaces described below (e.g., the conductive features 806a, 806b of FIG. 8A). In some embodiments, the second electrode 223 of the second LED 203 may be formed over the second LED 203.

In some embodiments, A1 and A2 of FIG. 2 correspond to the dotted lines Al and A2 of FIG. 1B. For example, Al may correspond to a functional LED (e.g., first LED 202a) while A2 corresponds to a defective LED (e.g., first LED 202b). In some embodiments, a second LED 203 is disposed vertically adjacent to the first LED 202b. The second LED 203 may be a top-emitting LED or a bottom-emitting LED. The second LED 203 may have inverse and/or different emission to the first LED 202b it is stacked over. The second LED 203 may be bonded to the first electrode 206, coupling the second LED 203 to the driving circuitry of the first LED 202b. In some embodiments, a conductive via 210 connects a second electrode 223 of the second LED 203 with the second electrode 204 of the first LED 202b. The conductive via 210 may comprise a conductive material (e.g., Cu, Al, ITO, or any suitable conductive and reflective material). The second electrode 223 of the second LED 203 may comprise a conductive material (e.g., Cu, Al, ITO, or any suitable conductive and reflective material). The second LED 203 may comprise a reflective coating 222 (e.g., reflective metal) to direct the emission of light of the second LED 203. The reflective coating may comprise a reflective material (e.g., Al, ITO or any suitable reflective material). In some embodiments, an insulation material (e.g., dielectric and/or oxide) may be padded between the second electrode 223 of the second LED 203 and the reflective coating 222 to prevent the flow of electrons through the reflective coating 222.

In some embodiments, a first plurality of LEDs (e.g., LEDs 202a) or a first layer of LEDs may be bottom-emitting LEDs, and second LED(s) (e.g., LED 203) or a second layer of LED(s) may be top-emitting LEDs. In some embodiments, a first plurality of LEDs or a first layer of LEDs may be top-emitting LEDs, and second LED(s) or a second layer of LED(s) may be bottom-emitting LEDs. For example, first LED 202a and first LED 202b may be replaced with a top-emitting LED (e.g., similar to LED 203 and with relevant electrical connectors), and second LED 203 may be replaced with a bottom-emitting LED (e.g., similar to LED 202a and with relevant electrical connectors).

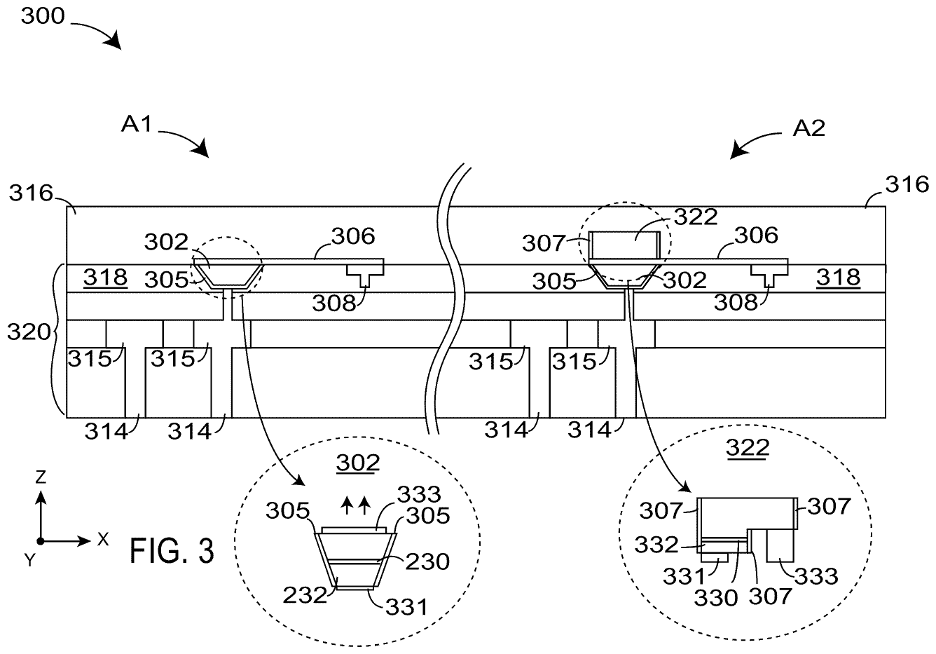

FIG. 3 schematically illustrates an embodiment of a display device 300, in accordance with some embodiments of the present disclosure. In some embodiments, the display device 300 is the same or similar to display device 200, except that first LEDs 302 and second LED 322 (and corresponding electrodes and connectors) is used in place of first LEDs 202a, 202b and second LED 203, respectively. In some embodiments, the substrate 320, the material layer 318, electrodes 306, passivation layer 316, interconnects 315, and vias 314 may correspond to (e.g., be the same as or similar to) substrate 220, material layer 218, electrodes 206, passivation layer 216, interconnects 215, and vias 214 described in FIG. 2, respectively.

In some embodiments, the display device 300 comprises a plurality of first LEDs 302 disposed in the material layer 318. In some embodiments, the material layer 318 comprises the same material as the passivation layer 216. For example, the passivation layer 318 may be transparent or semi-transparent to the visible wavelengths (e.g., wavelengths emitted from the first LEDs 302 of the display device 300). The passivation layer may comprise dielectric materials and/or oxide materials. Some specific examples include but are not limited to epoxy, acrylic (polyacrylate), poly methacrylate (PMMA), poly-carbonate (PC), benzocyclobutene (BCB), polyimide, and polyester, or any suitable material.

In some embodiments, the first LED 302 may be top-emitting LED. A close-up illustration is provided for the first LED 302, outlined by the dotted circle. The embodiments from the close-up illustration may be applied to any applicable LED described in this disclosure (e.g., any of the first LEDs, or second LEDs). The reflective layer 305 of the first LED 302 may be the same as or similar to the reflective layer 222 of the second LED 203 in FIG. 2. The first LED 302 may comprise a bottom contact (e.g., first contact 331) and a top contact (e.g., second contact 333), the first contact 331 and second contact 333 may be the same as or similar to the first contact 231b and second contact 233b in FIG. 2. The first contact 331 may be connected to circuitry (e.g., interconnects 315, vias 314) of the display device 300. The second contact 333 may be connected to an electrode 306.

In some embodiments, a connector 308 is disposed in the material layer 318. The connector 308 may electrically couple the electrode 306 to the circuitry of the display device 300. In some embodiments, as illustrated in FIG. 3, the connector 308 may be a different shape to the connector 208 of FIG. 2. The connector 308 may be the same as or similar to the connector 208 in FIG. 2.

In some embodiments, A1 and A2 of FIG. 3 correspond to the dotted lines A1 and A2 of FIG. 1B. For example, Al may correspond to a working or functional LED (e.g., first LED 302) while A2 corresponds to a defective LED (e.g., first LED 302). In some embodiments, a second LED 322 is disposed vertically adjacent to the defective LED 302 (e.g., first LED 302 of A2). In some embodiments, the second LED 322, as illustrated in FIG. 3, comprises of a different shape to the first LED 302. In some embodiments, the second LED 322 may comprise a reflective coating 307 (e.g., reflective metal) to direct, at least in part, the emission of light. The reflective coating 307 may comprise a reflective material (e.g., Cu, Al or any suitable reflective material).

A close-up illustration is provided for the second LED 322, outlined by the dotted circle. The embodiments from the close-up illustration may be applied to any applicable LED described in this disclosure (e.g., any of the first LEDs, or second LEDs). In some embodiments, the second LED 322 comprises a two bottom contacts (e.g., bonding pads), a first contact 331 and a second contact 333. In some embodiments, the first contact 331 and second contact 333 of the second LED 322 are individually connected to a first electrode and a second electrode of the LED 322 through the bottom contacts. For example, although not shown, corresponding electrical connections may be formed to connect the bottom contacts of the LED 322 to respective electrodes. In some embodiments, the LED 322 may comprise an active layer 330 (e.g., multiple quantum well structure(s)) and semiconductor layer (or layers 332) on either side of the active layer (e.g., p-doped and n-doped layers, respectively). In some embodiments active layer 330 may be similar to or the same as active layer 230, and semiconductor layer (or layers) 332 may be similar to or the same as semiconductor layer (or layers) 232. In some embodiments, a reflective coating 307 may be adjacent to any suitable portion of the LED 332 (e.g., bottom or side surfaces of LED 332, or portions thereof). In some embodiments, the LED may be flip chip replacement LED with both contacts on the bottom. In some embodiments, the contact 333 may be bonded to the electrode 306 while the contact 331 may be bonded to the circuitry of the first LED (e.g., another electrode, interconnects 315, vias 314). In some embodiments, a redistribution layer is disposed under the second LED 322, the redistribution layer may have similar features to the redistribution layer 740 described below. Additionally, the redistribution layer may comprise a plurality of respective vias and interconnects to connect the first contact 331 and the second contact 333 to appropriate input/output circuitry.

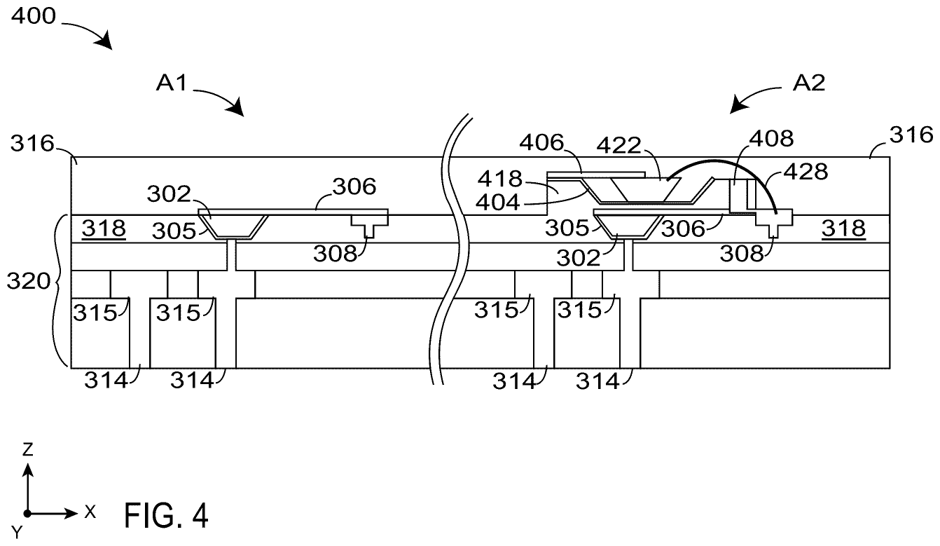

FIG. 4 schematically illustrates an embodiment of a display device 400, in accordance with some embodiments of the present disclosure. The display device 400 may have similar features to the display device 300 described above, and therefore the description of similar features is omitted for brevity. In some embodiments, the display device 400 is the same as display device 300, except an assembly or device package is used in place of second LED 322.

In some embodiments, the assembly comprises LED 422, a first electrode 406, a material layer 418, a second electrode 404 (e.g., reflector bank), and a connector 408. The assembly may have similar features to elements described in FIG. 2, and therefore the description of similar features is omitted for brevity. For example, the first electrode 406 may correspond to (e.g., be the same as or similar to) the first electrode 206. The material layer 418, second electrode 404, connector 408 may correspond to the material layer 218, second electrode 404, and connector 208, respectively. In some embodiments, the LED 422 may be the same as the first LED 202a. In some embodiments, the LED 422 may be the same as the second LED 203.

In some embodiments, the LED 422 may be electrically connected to the driving circuitry of the first LED 302 (e.g., defective LED at A2) by a wire 428. In some embodiments, the LED 422 may be electrically connected to the driving circuitry of the first LED 302 (e.g., defective LED at A2) by bonding (e.g., directly bonding, hybrid bonding) a connector of the assembly to a bond pad. In some embodiments, the LED 422 may be electrically connected to the driving circuitry of the first LED 302 by wire bonding a contact of the first LED to a bonding pad. The bonding pad may be connected to an electrode of the first LED. In some embodiments, a contact (e.g., top contact, bottom contact, first contact, second contact) of LED 422 may be connected to an electrode (e.g., top electrode, bottom electrode, first electrode, second electrode) of the first LED by wire bonding, direct bonding, or forming electrical connectors to the electrode.

In some embodiments, the assembly is disposed within the passivation layer 316 of the display device 400.

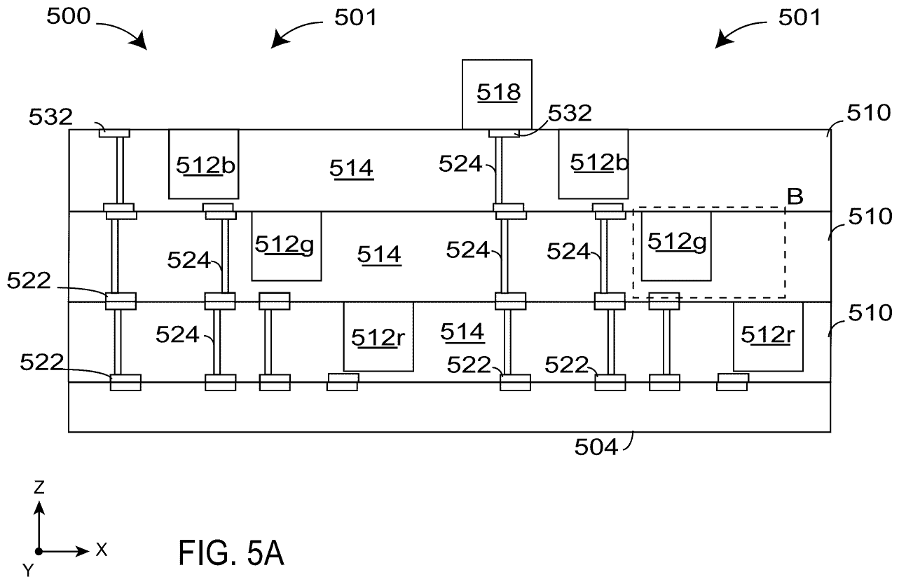

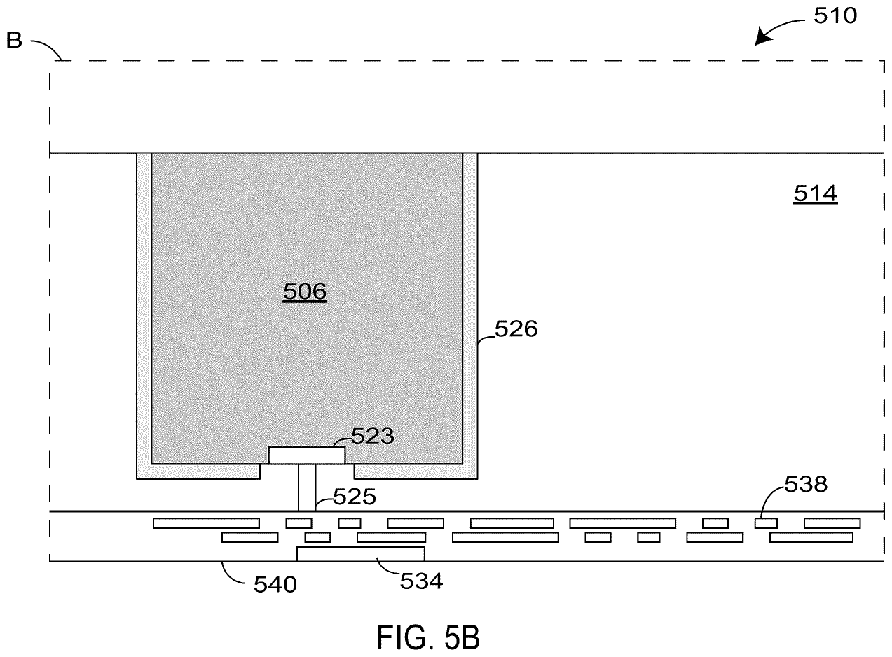

FIG. 5A depicts a cross-sectional view of a display 500. The display 500 comprises a stack of substrates including a first substrate 504 and a plurality of second substrates 510. The first substrate 504 may be directly bonded (e.g., hybrid bonded) to a vertically adjacent second substrate 510, without any intervening adhesive. Each second substrate 510 may be directly bonded (e.g., hybrid bonded) to a vertically adjacent second substrate 510, without any intervening adhesive. The display 500 may comprise a plurality of pixels 501.

In some embodiments, the first substrate 504 comprises a plurality of singulated control devices embedded within a first dielectric layer. Each control device is electrically connected to one or more of the LEDs (e.g., LED 512r, LED 512g, LED 512b) via direct hybrid bonds formed between the first substrate 504 and second substrates 510 (e.g., bonding of conductive features or bond pads disposed in respective dielectric layers). Additional detail regarding hybrid bonds and hybrid bonding of substrates may be found in the present disclosure, e.g., at least at the description of FIGS. 8A and 8B. In some embodiments, in place of the first substrate 504 comprising multiple control devices (e.g. dies) embedded or disposed in a dielectric layer (e.g., reconstituted substrate or wafer), the first substrate 504 may comprise a wafer (e.g., control or controller device wafer, device wafer, ROIC wafer, or a full wafer).

In some embodiments, the second substrates 510 may include a plurality of singulated LEDs (e.g., LED 512r, LED 512g, LED 512b) disposed in a respective second dielectric layer (e.g., dielectric layer 514). Each respective second substrate 510 may comprise LEDs that emit a same color light (e.g., reconstituted red LED substrate, reconstituted blue LED substrate, and reconstituted green LED substrate) or each respective second substrate layer may comprise LEDs that emit a different color light (e.g., a reconstituted substrate with red, green, and blue LEDs).

In some embodiments, the second dielectric layer 514 may include silicon oxide (SiO₂), silicon nitride (Si₃N₄), doped silicon oxide for better optical transmission or polymers for the same. In some embodiments, the second dielectric layer 514 of different second substrates 510 comprise a same material. In some embodiments, the second dielectric layer 514 of different second substrates 510 comprise a different material. In some embodiments, first or second dielectric layers 514 may comprise more than one layer of a same dielectric material or different dielectric materials.

As shown in FIG. 5A, a top second substrate 510 may comprise blue LEDs 512b, a middle or intermediate second substrate 510 may comprises green LEDs 512g, and a bottom second substrate 510 may comprise red LEDs 512r. Although display 500 shows the second substrates 510 having LEDs of a particular color in a particular layer, a display may have any suitable arrangement of stacked second substrates (e.g., top second substrate 510 comprises red LEDs 512r, intermediate second substrate 510 comprises green LEDs 512g, and bottom second substrate 510 comprises blue LEDs 512b, etc.). In some embodiments, the display device 500 may comprise a singular second substrate 510 with LEDs embedded in the singular second substrate 510. In some embodiments, the display device 500 may comprise any suitable number of second substrates 510 (e.g., one, two or more, etc.). In some embodiments, LEDs 512b, 512g, 512r, and 518 may all be top-emitting LEDs. In some embodiments, LEDs 512b, 512g, 512r, and 518 may be top-emitting LEDs, bottom-emitting LEDs, or any suitable combination of top and bottom emitting LEDs. For example, LED 512b, 512g, 512r may be top emitting LEDs, and LED 518 may be a bottom emitting LED. For example, LEDs 512b, 512g, 512r may be a bottom emitting LED, and LED 518 may be a top emitting LED. For example, LED 512b, 512g, 512r may be any combination of a bottom or top emitting LEDs, and LED 518 may be a top emitting LED. For example, LED 512b, 512g, 512r may be any combination of a bottom or top emitting LEDs, and LED 518 may be a bottom emitting LED. In some embodiments, LEDs 512b, 512g, 512r, and 518 may not overlap in a vertical direction. In some embodiments, LEDs 512b, 512g, 512r do not overlap in a vertical direction, and LED 518 may overlap with one of LEDs 512b, 512g, 512r in a vertical direction (e.g., when one of LEDs 512b, 512g, 512r is defective).

In the display 500, the LEDs (e.g., LED 512r, LED 512g, LED 512b) of each second substrate 510 are horizontally offset relative to the LEDs (e.g., LED 512r, LED 512g, LED 512b) in the vertically adjacent second substrate 510. Each control device may be electrically connected to one or more LEDs (e.g., LED 512r, LED 512g, LED 512b) via direct hybrid bonds formed between the first substrate 504 and the adjacent second substrates 510. Each control device, along with the connected LEDs 512, may form a pixel. These pixels may comprise at least three LEDs (e.g., green LED 512g, blue LED 512b, and red LED 512r), each emitting a distinct color of light, such as green, blue, and red.

In some embodiments, the second substrate 510 comprising a plurality of singulated LEDs disposed in a second dielectric layer 514, may include an interconnect layer or redistribution layer (e.g., redistribution layer 540 in FIG. 5B) such as a redistribution layer (RDL). In some embodiments, each LED is communicatively coupled to a respective control device via a respective set of bond pads 522, and vias 524. In some embodiments, within and/or adjacent to each pixel of the display device 500 is a set of bond pads and vias that connect to a topmost bond pad 532. In some embodiments, topmost bond pad 532 is similar to bond pads 522. The topmost bond pad 532 may be used to bond additional LEDs (e.g., LED 518) to a pixel if an LED of the pixel is determined to be defective (e.g., any of LEDs of side A2).

In some embodiments, a replacement LED may be directly bonded to a top of a defective LED. For example, a top routing layer may be provided on top of the pixel or defective LED. The top routing layer may comprise transparent conductors (e.g., ITO). In some embodiments, a replacement LED may be directly bonded to vertically overlap a defective LED (e.g., on the topmost second substrate 510 to overlap in a vertical direction with an underlying defective LED (e.g., any of LED 512b, 512g, 512r when the LED is defective).

In some embodiments, the display device comprises a first substrate (e.g., first substrate 504) and a second substrate (e.g., top second substrate 510 or any suitable second substrate). The first substrate comprises a plurality of control devices. The second substrate comprises a plurality of first LEDs (e.g., LEDs 512b or any suitable LEDs) embedded in a dielectric layer (e.g., first dielectric layer, dielectric layer 514). At least one second LED (e.g., LED 518) is directly bonded to the second substrate to connect the at least one second LED to a control device in the first substrate through at least one via (e.g., via 524) in the second substrate.

In some embodiments, the display device may further comprise a bottom second substrate (e.g., bottom second substrate 510 or any suitable second substrate). The bottom second substrate may comprise a plurality of third LEDs (e.g., LEDs 512r or any suitable LEDs) embedded in a second dielectric layer (e.g., dielectric layer 514). The control device may be connected to the at least one second LED (e.g., LED 518) through at least one via (e.g., via 524) in the bottom second substrate. The display device may further comprise an intermediate second substrate (e.g., intermediate second substrate 510 or any suitable second substrate). The intermediate second substrate may comprise a plurality of fourth LEDs (e.g., LEDs 512g or any suitable LEDs) embedded in a third dielectric layer (e.g., dielectric layer 514). The control device may be connected to the at least one second LED through at least one via (e.g., via 524) in the intermediate second substrate.

In some embodiments, a method may comprise providing the first substrate (e.g., first substrate 504) and at least one of, each, or a combination of the second substrates (e.g., top, bottom, and intermediate second substrates 510). The method may comprise directly bonding or hybrid bonding the at least one second LED (e.g., LED 518) to the second substrate (e.g., top second substrate 510 or any suitable second substrate). The method may comprise directly bonding or hybrid bonding adjacent substrates. For example, the method may comprise directly bonding or hybrid bonding the bottom second substrate to the first substrate, directly bonding or hybrid bonding the intermediate second substrate to the bottom second substrate, and directly bonding or hybrid bonding the top second substrate to the intermediate second substrate. In some embodiments, the second substrates may be directly bonded or hybrid bonded to form stacked second substrates, and the stacked second substrates may be directly bonded or hybrid bonded to the first substrate.

In FIG. 5B, a dotted box B highlights a zoomed-in view of a portion of the display 500, as shown in FIG. 5A. For example, FIG. 5B shows detailed features such as a reflective layer 526, electrodes 523, connectors 525, and redistribution layer 540 comprising interconnects 538 that include conductive wiring and conductive vias. The features shown in FIG. 5B may be applied to any suitable display (e.g., display 100, display 200, display 300, display 400, or any suitable display described throughout the present disclosure). In some embodiments, the features of box B can be applied to any suitable LED, such as LED 512b, LED 512r, and LED 518 of FIG. 5A, or any suitable LED in the display described in the present disclosure.

FIG. 5B illustrates a detailed view of the dotted box B where sections of a reflective layer 526 is disposed between adjacent LEDs (e.g., LED 512g). In some embodiments, LED 506 is the same as LED 512g. The reflective layer 526 is disposed or positioned between each LED 506 and a dielectric layer. The reflective layer 526 may comprise a reflective metal or material (e.g., a metal material such as aluminum (Al) silver (Ag) or gold (Au), etc., or a combination thereof) or composite of metals. In some embodiments, the reflective layer 526 may comprise distributed Bragg Reflector (DBR) coatings The inclusion of the reflective layer 526 may enhance the luminance of the light output from the surface of the display and may also be used to prevent optical cross talk between LEDs 506. When electrical current flows through a LED 506, incoherent light is emitted in all directions. A reflective layer 526 enables light emitted towards the reflective layer 526 to be directed towards a viewing surface of the display 500. For example, the reflective layer 526 reflects light emitted from the LED 506 back towards a viewing surface of the display 500, increasing the brightness and contrast of the display 500. In some embodiments, a reflective layer 526 is used in applications where high visibility is relevant, such as outdoor displays or high-definition screens. The reflective layer 526 may serve as a protective barrier for the LEDs 506 from environmental factors and may extend the lifespan of the display. In some embodiments, shape the non-horizontal wall (e.g., sidewalls) of the reflector layer may comprise a parabolic or hyperbolic shape for a parabolic or hyperbolic reflector.

In some embodiments, a light-absorbing layer (not shown) may be disposed or positioned between adjacent LEDs 506. The light-absorbing layer comprising a light-absorbing material may be disposed between the reflective layer 526 and dielectric layer 514. The light-absorbing material may significantly reduce optical crosstalk between neighboring LEDs 506. In some embodiments, the light-absorbing material comprises a metallic, resin, or polymer material.

In some embodiments, the intermediate substrate 510 comprising a plurality of singulated LEDs 506 disposed in a dielectric layer 514, may include an interconnect layer or redistribution layer 540, such as a redistribution layer (RDL). In some embodiments, the intermediate substrate 510 may comprise a vertical connection (e.g., through substrate via or TSV, via 728b as shown in FIG. 7) electrically connecting a top side of the intermediate substrate 510 to the bottom side of the intermediate substrate 510. The electrodes 523 of the LEDs 506 are electrically connected to conductive features (e.g., bond pads 534) via connectors 525 through interconnects 538 in the interconnect layer or redistribution layer 540. The bond pads 534 embedded in a dielectric layer, can be hybrid bonded to bond pads of a control device (e.g., a processor or controller, ROIC, etc.) embedded, in some embodiments, in the layer below what is shown in FIG. 5B. The bond pads 534, electrodes 523, connectors 525, and interconnects 538 may comprise any suitable conductive material. For example, a conductive material may include metals such as copper or copper alloys, nickel, aluminum, or alloys, conductive oxide material such as indium tin oxide (ITO).

FIGS. 6A-6C schematically illustrates aspects of example methods of forming a display device, according to some embodiments. In some embodiments, the example method may be used to form the display device 200 of FIG. 2.

At block 60, the method includes providing a plurality of first LEDs (e.g., LEDs 202a, 202b) on substrate 220. For example, the method may include attaching first LEDs to a substrate (e.g., CMOS/TFT backplane) and integrating the first LEDs with the substrate. The substrate 220 may comprise electrodes 204. Attaching the first LEDs may comprise bonding (e.g., direct bonding, hybrid bonding) conductive features disposed on the LED (e.g., contact 233) to conductive features (e.g., electrode 204, reflective bank, bond pad) on the substrate 220.

Integrating the first LEDs with the substrate may include forming electrodes or electrical connections to the first LEDs (e.g., electrode 206, connector 208 disposed in dielectric layer 216a). In some embodiments, the first LEDs may be part of a reconstituted substrate or wafer that is attached to a CMOS/TFT backplane. For example, reconstituted substrate or wafer may comprise the material layer 218, electrode 204, LED 202a, LED 202b, and electrode 206. In some embodiments, the reconstituted substrate or wafer may further comprise a passivation layer or dielectric layer that the electrode 206 is disposed in. The reconstituted substrate or wafer may be attached to a CMOS/TFT backplane (e.g., structure underlying material layer 218).

At block 60, the method may include testing the first LEDs to determine which LEDs are defective. In some embodiments, a luminance camera may be used to identify a luminance readout of each LED on the display (e.g., display of first LEDs) during the manufacturing process of the display. The luminance camera may transmit images taken of the display to an image processor device that may detect and label the luminance value of each LED. An LED may be determined to be defective if the luminance output is below a standard luminance value. If an LED is determined to be defective, a replacement LED (e.g., working LED) may be stacked on top of the defective LED (e.g., as described in block 61). In some embodiments, a replacement LED may be stacked on a working LED. In some embodiments, a replacement LED may be stacked on a missing LED.

At block 61, the method includes transferring second LED(s). For example, the method may include picking and placing LED 203 to a surface of the display at block 60, with the emitting surface of the LED 203 facing up. The method may include bonding (e.g., direct bonding, hybrid bonding) the LED 203 to electrode 206. In some embodiments, the bonding may be done with ITO Zibond. For example, a contact on LED 203 and/or the electrode 206 may comprise ITO material.

At block 62, the method includes depositing a second passivation layer 216b.

At block 63, the method includes forming openings (e.g., holes, vias) in the passivation layer to expose the bottom electrode (e.g., second electrode 204) of the LED (e.g., LED 202b). For example, the passivation layer (e.g., passivation layers 216a and 216b) may comprise an inorganic dielectric material (e.g., SiO₂) and an opening may be formed in the passivation layer using photolithography and etching. As another example, the passivation layer (e.g., passivation layers 216a and 216b) may comprise an organic dielectric material (e.g., polyimide) and an opening may be formed in the passivation layer using laser ablation. In some embodiments, direct-write lithography may be used for maskless patterning.

At block 64, the method may include filling a conductive material (e.g., conductive via 210) in the openings. For example, the method may include forming an electrode (e.g., second electrode 223, top electrode) of LED 203. In some embodiments, the method includes depositing a dielectric layer to dispose electrode 223 in a dielectric layer to form display 200 of FIG. 2.

In some embodiments, a method may comprise hybrid bonding a reconstituted substrate 692 (e.g., reconstituted wafer) on a top surface of a display 690 as shown in block 67 to form display 200 of FIG. 2. For example, subsequent to block 60, the method may proceed to blocks 66 and 67.

At block 66, the method includes forming DBI layer on a top surface of a display 690. For example, the method may include forming a passivation layer 216c where the electrode 206 is disposed in the passivation layer 216c. A conductive via 210a may be formed in the passivation layer 216a and 216c. The DBI layer may comprise conductive features (e.g., electrode 206 and via 210a) disposed in a dielectric layer (e.g., passivation layer 216c). The display 690 may comprises LEDs 202a and 202b electrically connected to a CMOS/TFT backplane.

At block 67, the method includes hybrid bonding a reconstituted substrate 692 to the display 690. The reconstituted substrate 692 may comprise a second LED 203 disposed in a passivation layer 216d. In some embodiments, although not shown at block 67, the electrode 223 may be disposed in the passivation layer 216d.

FIG. 7 shows a schematic of an example method to form a display through heterogenous pixel integration, where singulated LED 706 from RGB wafers can be integrated to form a composite RGB pixel. In some embodiments, the example method shows forming a substrate. In some embodiments, singulated LED 706 may correspond to (e.g., be similar to or same as) LEDs 106a-c, LED 406c, LED 706, or any suitable LED described in the present disclosure.

At block 70, the method includes singulating a wafer to form pixel-size chips or chiplets. For example, a wafer of singulated LEDs 706 may be placed on a tape frame or temporary carrier 716 and singulated to form LED chips or chiplets. The singulated LED chips or chiplets may be about 1×1 micron², about 5×5 micron², about 10×10 micron², to about 40×40 micron² or any suitable LED size for a pixel. In some embodiments, any suitable wafer (e.g., wafer of blue LEDs, wafer of green LEDs, wafer of any suitable color, etc.) may be placed on a tape frame and singulated. The method may further include stretching the temporary carrier 716 to space apart neighboring chips or LEDs (e.g., singulated LEDs 706), shown at block 71.

At block 71, the method includes spacing apart singulated chips or chiplets. In some embodiments, the method of spacing singulated LED chips (e.g., singulated LEDs 706) from diced wafers may include separation via dicing tape expansion (e.g., stretching temporary carrier 716). For example, the temporary carrier 716 may be stretched to create uniform spacing between neighboring singulated LEDs (e.g., singulated LEDs 706). A spacing of about 1 to 40 microns between neighboring singulated LEDs (e.g., singulated LEDs 706) may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 72, the method includes transferring the singulated chips or chiplets to a carrier substrate. For example, singulated LEDs 706 are transferred to a carrier substrate 720 via bonding or adhesive. Before or after transferring, diffusion regions may be removed from the LEDs and first electrodes 723 may be formed. In some embodiments, both electrodes (e.g., first and second electrodes) may be formed to the LEDs based on the design. The method may include forming a reflective layer 726 over the plurality of singulated LED (e.g., singulated LEDs 706). The reflective layer 726 may comprise a reflective metal (e.g., Ag, Au, or Al, etc.) or DBR coatings. One or more dielectric layers (e.g., adhesion, isolation, passivation, barrier, etc.) may be deposited before and/or after the reflective layer 726 is formed. In some embodiments, the reflective layer may comprise of a distributed Bragg reflector. In some embodiments, a reflective material (e.g., reflective layer 726) may be coated on non-light-emitting sides of each LED 706. In some embodiments, a light-absorbing layer may be disposed or positioned between adjacent LEDs 706. The light-absorbing layer comprising a light-absorbing material may be disposed between the reflective layer 726 and a dielectric layer 708. The light-absorbing material may significantly reduce optical crosstalk between neighboring LEDs 706. In some embodiments, the light-absorbing material comprises a metallic, resin, or polymer material.

At block 73, the method includes forming a reconstitution dielectric over the singulated chips or chiplets. For example, the dielectric layer 708 is formed over the reflective layer 726. The dielectric layer 708 may comprise silicon oxide or a suitable dielectric material tuned to transmit a specific wavelength range (e.g., corresponding to a color of light emitted from an LED of bonded adjacent substrate behind/below dielectric layer 708). In some embodiments, the dielectric layer 708 may correspond to (e.g., be the same or similar to) dielectric layers 108a-c.

At block 74, the method includes forming electrical connectors to the chip or chiplets. For example, electrical connectors 725 are formed to contact the electrodes 723 of singulated LEDs 706. The method may include forming vias 728a and 728b through the dielectric layer 708. The vias 728a-b may enable electrical connections through the dielectric layer 708 to neighboring substrates via hybrid bonding. The electrical connectors 725 and vias 728a-b may comprise a same or different material and may be any suitable conductive material such as those described in the present disclosure. In some embodiments, the method of forming the electrical connectors 725 and vias 728a-b may comprise depositing or coating a suitable adhesion layer over a patterned cavity corresponding to the electrical connector 725 and/or vias 728a-b, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric layer 708. In some embodiments, the connectors 725 and vias 728a-b may comprise wirebonds, formed by wirebonding operations. In other embodiments, the connectors 725 and vias 728a-b may be formed by 3D printing methods or screen printing methods.

At block 75, the method includes forming a direct bonding interface (DBI) layer (e.g., bottom DBI layer). For example, the method comprises forming a redistribution layer 740 comprising conductive features or bond pads 734 and interconnects 738 in a dielectric layer.

At block 76, the method includes transferring the reconstituted wafer to another substrate. For example, the method includes transferring the reconstituted singulated singulated LEDs 706 and redistribution layer 740 to substrate 722 (e.g., another carrier or a target wafer) and removing the first carrier 720. In some embodiments, the reconstituted wafer comprising singulated singulated LEDs 706 can be transferred to or hybrid bonded to another reconstituted wafer (comprising LEDs and/or control device) or another wafer comprising control devices (e.g., control or controller device wafer, device wafer, ROIC wafer, full wafer, etc.). The method may include forming second electrodes 732 of the LEDs 706. The method may include forming another DBI layer (e.g., top DBI layer). For example, the method includes forming a redistribution layer 740 comprising interconnects 738 and bond pads 734 in a dielectric layer.

In some embodiments, the method shown in FIG. 7 can be modified to form any suitable substrates such as those mentioned in the present disclosure. For example, at block 76, method may include multiple transfer steps, where different types of LEDs (e.g., singulated wafer of red LEDs, singulated wafer of green LEDs, singulated wafer of blue LEDs, etc.) and/or singulated control devices may be transferred.

In some embodiments, the method includes hybrid bonding to electrically connect each control device to one or more of the LEDs to form a pixel. For example, at block 74 the substrate 722 may be a target substrate and the reconstituted wafer may be a substrate. For example, the substrate may be hybrid bonded to additional substrates (e.g., via redistribution layer 740) and the substrate may be hybrid bonded to a processor substrate, reconstituted substrate or wafer, etc. (e.g., via redistribution layer 740). Hybrid bonding the substrate to a processor substrate may electrically connect a control device to one or more LEDs of the second substrates. Each control device and the one or more LEDs electrically connected thereto may form a pixel.

In some embodiments, where there are more than one stacked layer, the display may further comprise light guides. For example, the method may include forming deep-trench isolation with metal fill that guides light emitted from the LEDs of at least of the first substrates or the second substrate to a surface of the display. For example, the method may include forming channels with metal coatings to form light guides. In some embodiments, the method may include forming a dielectric fill on the metal coatings in the channels.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564 , filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 1B, a bonded structure 800 comprises the first and second elements 802 and 804 that are directly bonded to one another at a bond interface 818 without an intervening adhesive.

Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/°° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 722, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 1A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 um, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosed subject matter.

1. A display device comprising:
a plurality of first LEDs disposed in a first passivation layer, each first LED having a first electrode disposed on the respective first LED and a second electrode that is electrically coupled to a control device;
a contact of at least one second LED directly bonded to the first electrode of at least one first LED, wherein the at least one second LED and the first electrode of the at least one first LED are disposed in a second passivation layer; and
an electrode of the at least one second LED is electrically connected to a same control device that the second electrode of the at least one first LED is connected to.

2. The display device of claim 1, wherein the plurality of first LEDs are bottom-emitting LEDs, and the at least one second LED is a top-emitting LED.

3. The display device of claim 1, wherein the plurality of first LEDs are top-emitting LEDs, and the at least one second LED is a bottom-emitting LED.

4. The display device of claim 1, wherein each of the plurality of first LEDs are disposed in a reflective layer disposed in the first passivation layer, the reflective layer surrounding bottom and side surfaces of a respective first LEDs to direct light emitted from the respective first LEDs towards a display surface.

5. The display device of claim 1, wherein the at least one second LED comprises a reflective layer on sidewalls of the at least one second LED to direct light emitted from the at least one second LED towards a display surface.

6. The display device of claim 1, wherein the at least one first LED and the at least one second LED have different geometric structures.

7. The display device of claim 1, wherein each of the first LEDs is embedded in sidewall mirrors.

8. The display device claim 1, wherein the electrode of the at least one second LED is wire bonded to a bond pad to connect to the same control device that the second electrode of the at least one first LED is connected to.

9. The display device of claim 1, wherein the first electrode of each first LED comprises indium tin oxide.

10. The display device of claim 1, wherein the first electrode of each first LED comprises copper.

11. The display device of claim 1, wherein the display device is a microLED display device.

12. A method for manufacturing a display device, the method comprising:
providing a substrate comprising a plurality of first LEDs disposed in a first passivation layer, wherein each first LED comprises a respective first electrode and a respective second electrode; and
directly bonding a contact of at least one second LED to at least one first electrode of at least one first LED.

13. The method of claim 12, further comprising:
depositing a second passivation layer to dispose the second LED in the second passivation layer.

14. The method of claim 13, further comprising:
forming electrical vias in the second passivation layer and the first passivation layer by:
creating an opening in the second passivation layer to expose the second electrode of the at least one first LED, the opening adjacent to the at least one first LED and the at least one second LED; and
depositing a conductive material in the opening to connect the second electrode of the at least one first LED to an electrode of the at least one second LED.

15. The method of claim 14, wherein:
the first and second passivation layer comprises polyimide; and
creating the opening comprises laser ablating a portion of the first and second passivation layers.

16. The method of claim 12, further comprising:
prior to directly bonding, testing luminance values of each first LED to identify the at least one first LED as a defective LED.

17. The method of claim 12, wherein providing the substrate comprises:
attaching the plurality of first LEDs to a complementary metal-oxide semiconductor (CMOS) and/or thin film transistor (TFT) backplane.

18. The method of claim 12, wherein providing the substrate comprises:
attaching the plurality of first LEDs to a reconstituted wafer comprising control devices.

19. The method of claim 12, further comprising:
wire bonding an electrode of the at least one second LED to a bond pad to connect the electrode of the at least one second LED to the second electrode of the at least one first LED.

20-25. (canceled)
